(19) United States
(12) Patent Application Publication
(10) Pub. No.: US 2006/0083996 A1
(43) Pub. Date: Apr. 20, 2006

(54) Apparatus for exposing a substrate, photomask and modified illuminating system of the apparatus, and method of forming a pattern on a substrate using the apparatus

(76) Inventor: Ho-Chul Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/245,223

(22) Filed: Oct. 7, 2005

(30) Foreign Application Priority Data
Oct. 11, 2004 (KR) 2004-81000

(51) Int. Cl. G03B 27/42; G03C 5/00; G06F 17/50; G03F 1/00

(52) U.S. Cl. 430/5; 430/30; 355/53; 716/19

(57) ABSTRACT

An exposure apparatus and photo-mask of the exposure apparatus can form a perpendicular line/space circuit pattern through only a single exposure process. The photo-mask includes a first line/space pattern oriented in a first direction, a second line/space pattern oriented in a second direction and lattice patterns, operating as polarizers, occupying the spaces of the line/space patterns. The exposure apparatus also includes a modified illuminating system. The modified illuminate system may be a composite polarization illuminating system having a shielding region, and a plurality of light transmission regions defined within the field of the shielding region. The light transmission regions are implemented as polarizers that polarize the light incident thereon in the first and second directions, respectively.

### BACKGROUND OF THE INVENTION

The present invention relates to an exposure apparatus of photolithographic equipment used in the fabricating of a semiconductor device or the like. More particularly, the present invention relates to a photo-mask and an illuminating system of the exposure apparatus.

The fabricating of an integrated circuit of a semiconductor device includes a photolithography process in which a pattern of a photo-mask is transcribed onto a wafer photoresist layer (WPR), i.e., a layer of photoresist coating a wafer. More specifically, the photo-mask is illuminated using a light source and an illuminating system to pick up an image of the pattern of the photo-mask. The pattern of the photo-mask corresponds to a circuit pattern that is to be formed on the wafer.

A line/space circuit pattern is representative of the circuit patterns that are typically formed on a wafer. A photo-mask for use in forming such a line/space circuit pattern is illustrated in FIGS. 1 and 2. A line/space pattern 18 of the photo-mask 10 of FIG. 1 consists of a pattern of lines 14 that run parallel to each other in a horizontal direction (the direction of the X axis) and are separated from each other by spaces 16. The lines 14 are made of chrome and are formed on a quartz substrate 12. On the other hand, a line/space pattern 28 of the photo-mask 10 of FIG. 2 consists of a pattern of lines 24 that run parallel to each other in a vertical direction (the direction of the Y axis) and are separated from each other by spaces 26. The lines 24 are made of chrome and are formed on a quartz substrate 22.

The light used to illuminate the photo-mask is directed onto the wafer such that the WPR is exposed to the image. The WPR is developed in a process that selectively removes the exposed or non-exposed portions of the WPR, thereby forming a WPR pattern. The WPR pattern thus formed by the photolithography process is used as a mask for etching a layer of material disposed under the WPR.

In this process, the line width of the WPR pattern is the most important technical variable in establishing the degree to which the final semiconductor device can be integrated. The degree of integration sets the price of the semiconductor device. Therefore, various research has been conducted on minimizing the line width of the WPR pattern.

In particular, much of the research has centered on increasing the resolution of the optics of the exposure apparatus. Rayleigh's equation (Equation 1 below) suggests ways of improving the resolution Wₘᵢₙ of the optics.
Wₘᵢₙ=k₁λ/NA [Equation 1]
wherein k1 is a constant associated with the exposure process, λ is the wavelength of the light emitted by the light source of the exposure apparatus, and NA is the numerical aperture of the optics of the exposure apparatus.

In order to obtain high resolution in an exposure process, it is thus necessary to minimize the wavelength λ of the light and the constant k₁, and to maximize the numerical aperture (NA). Efforts aimed at minimizing the wavelength of the light have yielded the ArF laser which can emit light having a wavelength of 193 nm, down from 436 nm which was the wavelength of light emitted by the G-line light sources prevailing in exposure apparatuses in 1982. Also, an F2 laser capable of emitting light having a wavelength of 157 nm is expected to be implemented sooner or later. Still further, recent improvements in the photo-mask, lens system of the exposure apparatus, composition of the photoresist, and controls of the exposure process have brought the process constant k₁ down to as low as 0.45.

On the other hand, the NA has recently been increased to no less than 0.7 in exposure apparatuses employing an ArF laser (193 nm), to over 0.3 in exposure apparatuses employing a G-line light source, and to 0.6 in exposure apparatuses employing a KrF laser (248 nm). Further increases in the NA are expected as the wavelength of the light put into use approaches that of the extreme ultra violet (EUV) band (13.5 nm). Also, a light source emitting light having a wavelength of 193 nm is expected to be used for a long time in exposure apparatuses that employ so-called immersion technology.

In addition, the defocusing degree of freedom (DOF), represented by Equation 2, must be high if a minute pattern having a stable profile and a small line width is to be formed on a wafer.
DOF=k₂*(Wₘᵢₙ)²/λ [Equation 2]

A modified illuminating system has recently been used to provide the high DOF required for forming a stable minute pattern having a small line width. The modified illuminating system gathers a large amount of light, in which interference has been created by the photo-mask, and directs the light towards the WPR. Therefore, the modified illuminating system allows for more of the information on the circuit pattern provided by the photo-mask to be transmitted to the WPR.

Moreover, the uniformity of the line width of the WPR pattern significantly affects the product yield; therefore, reducing the line width of the WPR without maintaining uniformity in the line width has no advantages. Accordingly, various techniques have been suggested for improving the uniformity of the line width of the WPR pattern. However, as mentioned above, the WPR pattern is fabricated by transcribing a pattern of a photo-mask onto the photoresist layer. Accordingly, the shape of the WPR pattern is affected by the characteristics of and shape of the pattern of the photo-mask. Therefore, the line width of the pattern the photo-mask must first be uniform before any technique aimed at improving the uniformity of the line width of the WPR pattern can be effective.

FIG. 3 is a flowchart illustrating typical processes in the fabricating of a photo-mask. Referring to FIG. 3, a circuit pattern of a semiconductor device is designed using a computer program (such as a CAD or OPUS program). The designed circuit pattern is stored in a predetermined memory as electronic data D1. Then, an exposure process (S2) is performed in which an electronic beam or a laser irradiates a predetermined portion of a photoresist film lying over a chrome layer on a quartz substrate. The region irradiated by the exposure process (S2) is determined by exposure data D2 extracted from the design circuit pattern data D1. The exposed photoresist film is then developed (S3). The development process (S3) removes select portions of the photoresist film, such as those which were irradiated, to thereby form a photoresist pattern. The photoresist pattern exposes the underlying chrome film. The exposed chrome film is then plasma dry-etched using the photoresist pattern as a mask to form a mask (chrome) pattern that corresponds to the circuit pattern and, in turn, exposes the quartz substrate (S4). Then, the photoresist pattern is removed whereupon the photo-mask is complete.

FIG. 4 schematically illustrates a perpendicular line/space circuit pattern 480, which is another type of pattern that must be typically formed on a wafer to produce a highly integrated semiconductor device. The perpendicular line/space circuit pattern 480 consists of a line/space circuit pattern 480a oriented in a horizontal direction (the direction of the X axis), and a line/space circuit pattern 480b oriented in a vertical direction (the direction of the Y axis) and which intersects the line/space circuit pattern 480a. Each of the line/space circuit patterns 480a, 480b consists of a series of parallel lines 440 separated from one another by spaces 460.

Two photo-masks and exposure processes are required to form the perpendicular line/space circuit pattern 480. The photo-masks are illustrated in FIGS. 5A and 5B. FIG. 5A illustrates a first photo-mask 50a including a line/space pattern 58a extending in a horizontal direction (the direction of the X axis). The line/space pattern 58a comprises a pattern of lines 54a of chrome extending parallel to one another on a quartz substrate 52a and separated by spaces 56a. FIG. 5B illustrates a second photo-mask 50b including a line/space pattern 58b extending in a vertical direction (the direction of the Y axis). The line/space circuit 58b comprises a pattern of lines 54b of chrome extending parallel to one another on a quartz substrate 52b and separated by spaces 56b.

First, a photoresist layer on a wafer (WPR) is exposed to light directed through the first photo-mask 50a via a first modified illuminating system in a primary exposure process. Then, the WPR is exposed to light directed through the second photo-mask 50b via a second modified illuminating system in a secondary exposure process. Then, the WPR is developed to form a photoresist pattern corresponding to the perpendicular line/space circuit pattern 480 of FIG. 4. In this case, the light transmission regions of the modified illuminating systems must be located at different relative positions because the line/space patterns of the first photo-mask 50a and the second photo-mask 50b are oriented in different directions from each other. For example, as shown in FIG. 6A, a dipole illuminating system 60a having light transmission regions 61a arranged in a vertical direction (the direction of the Y axis) is used to illuminate the first photo-mask 50a. On the other hand, as shown in FIG. 6B, a dipole illuminating system 60b having light transmission regions 61b arranged in a horizontal direction (the direction of the X axis) is used to illuminate the second photo-mask 50b.

The yield of the photolithography process is thus severely limited by the need to perform the above-described primary and secondary exposure processes. In addition, other manufacturing problems inevitably occur due to the delay between the primary exposure and secondary exposure processes and due to an overlap in the relative positions of the first photo-mask and the second photo-mask that occurs during the respective exposure processes.

### SUMMARY OF THE INVENTION

An object of the present invention is to overcome the above-described limitations of the prior art.

More specifically, an object of the present invention is to provide an exposure apparatus and method capable of being used to form a perpendicular line/space circuit pattern through only a single exposure process.

Another object of the present invention to provide a photo-mask that can transfer a sharp image of a line space pattern having a small critical dimension to a layer of photoresist.

Still another object of the present invention is to provide a photo-mask that can facilitate the forming of a perpendicular line/space circuit pattern through only a single exposure process.

Yet another object of the present invention is to provide a modified illuminating system which can enhance the transfer of the image of a perpendicular line/space pattern of a photo-mask to a layer of photoresist.

According to one aspect of the present invention, there is provided a photo-mask comprising a transparent substrate, a line/space pattern of opaque material on the substrate, and a latticed pattern of opaque material occupying the spaces of the line/space pattern. The lattice pattern is a series of stripes extending perpendicular to the lines of the line/space pattern, and the stripes have a pitch smaller than that of the wavelength of the exposure light. Accordingly, the latticed pattern operates as a polarizer. Therefore, the image of the line/space pattern is picked up by light polarized in a direction parallel to the lines of the line/space pattern. For example, when the line/space pattern is oriented in the direction of an X axis, the stripes of the lattice pattern extend in the direction of a Y axis orthogonal to the X axis. The pitch of the lattice pattern in the direction of the Y axis is smaller than the wavelength of the exposure light.

According to another aspect of the invention, the line/space pattern is a perpendicular line/space circuit pattern including a first line/space pattern oriented in a first direction and a second line/space pattern oriented in a second direction perpendicular to the first direction. In such a case, a first lattice pattern occupies the spaces of the first line/space pattern, and a second lattice pattern occupies the spaces of the second line/space pattern.

According to another aspect of the present invention, there is provided a composite polarization illuminating system for illuminating a photo-mask having a line/space patterns oriented in first and second directions. The composite polarization illuminating system is a combination of a first modified illuminating system having a light transmission region implemented as a polarizer that polarizes light in the first direction, and a second modified illuminating system having a light transmission region implanted as a polarizer that polarizes light in the second direction. Preferably, the second direction is perpendicular to the first direction. Therefore, the composite polarization illuminating system will illuminate the perpendicular line/space pattern of the photo-mask, during an exposure process, in a manner optimized for the line/space patterns.

According to another aspect of the invention, each light transmission region may have a dipole shape, or one light transmission region may have a dipole shape whereas the other light transmission region has an annular shape. Also, the light transmission regions may overlap. In this case, light that is not polarized is transmitted from the area of overlap of the light transmission regions.

According to still another aspect of the present invention, there is provided an exposure system comprising a light source, a photo-mask having a substrate that is transparent to the light emitted by the light source, a first line/space pattern oriented in a first direction, and a second line/space pattern oriented in a second direction, and a modified illuminating system interposed between the light source and the photo-mask to illuminate a select region of the photo-mask. The modified illuminating system comprises first and second polarizers that polarize the light incident thereon in the first and second directions, respectively. The photo-mask preferably also has a first lattice pattern occupying the spaces of the first line/space pattern, and a second lattice pattern occupying the spaces of the second line/space pattern. The first lattice pattern is in the form of a series of stripes extending perpendicular to the first direction. Likewise, the second lattice pattern is in the form of a series of stripes extending perpendicular to the second direction. Each series of stripes has a pitch that is smaller than the wavelength of the light emitted by the light source.

According to the present invention as described above, a multi-directional line/space circuit pattern, such as a perpendicular line/space circuit pattern, can be formed using only one photo-mask and a single exposure process.

### BRIEF DESCRIPTION OF THE DRAWINGS

These and other objects, features and advantages of the present invention will be better understood from the detailed description of the preferred embodiments thereof that follows with reference to the accompanying drawings. In the drawings:

FIGS. 1 and 2 are plan views of photo-masks having line/space circuit patterns, respectively, for use in forming minute circuit patterns on a wafer;

FIG. 3 is a flowchart of a prior art process of fabricating a photo-mask;

FIG. 4 is a plan view of a perpendicular line/space circuit pattern formed on a wafer;

FIGS. 5A and 5B are plan views of photo-masks, respectively, used for forming the perpendicular line/space circuit pattern of FIG. 4;

FIGS. 6A and 6B are each a plan view of a dipole modified illuminating system;

FIG. 7A is a plan view of to an embodiment of a photo-mask according the present invention;

FIG. 7B is a sectional view of the photo-mask taken along line I-I′ of FIG. 7A;

FIG. 8 is a plan view of a portion of another embodiment of a photo-mask according to the present invention, illustrating a perpendicular line/space pattern of the photo-mask;

FIGS. 9 to 11 are plan views of other embodiments of photo-masks according to the present invention;

FIG. 12 is a flowchart illustrating an embodiment of a process of fabricating a photo-mask according to the present invention;

FIG. 13 schematically illustrates an embodiment of a composite polarization modified illuminating system according to the present invention, for use in illuminating a photo-mask having a perpendicular line/space circuit pattern as shown in FIG. 8;

FIG. 14 schematically illustrates another embodiment of a composite polarization modified illuminating system according to the present invention for use in illuminating a photo-mask having a perpendicular line/space circuit pattern as shown in FIG. 8;

FIG. 15 is a schematic diagram of an exposure apparatus according to the present invention;

FIGS. 16A to 16G illustrate beams having various spatial profiles;

FIG. 17A is a plan view of a hologram pattern of a beam shaper according to the present invention;

FIG. 17B illustrates a spatial intensity distribution of the partial beam formed using a beam shaper having the hologram pattern illustrated in FIG. 17A;

FIGS. 18A to 18C illustrate a first embodiment of a polarization controller according to the present invention; and

FIGS. 19A and 19B illustrate a second embodiment of a polarization controller according to the present invention.

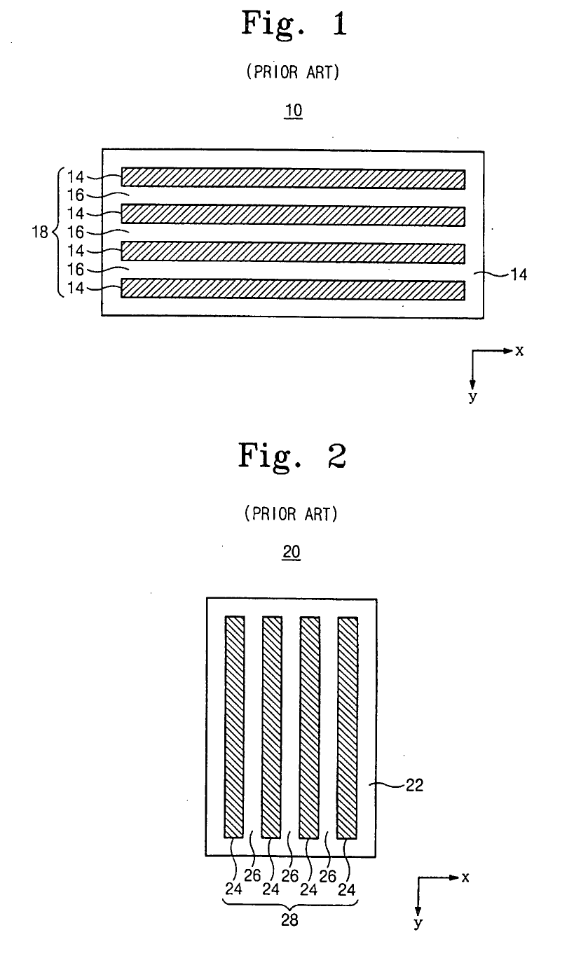

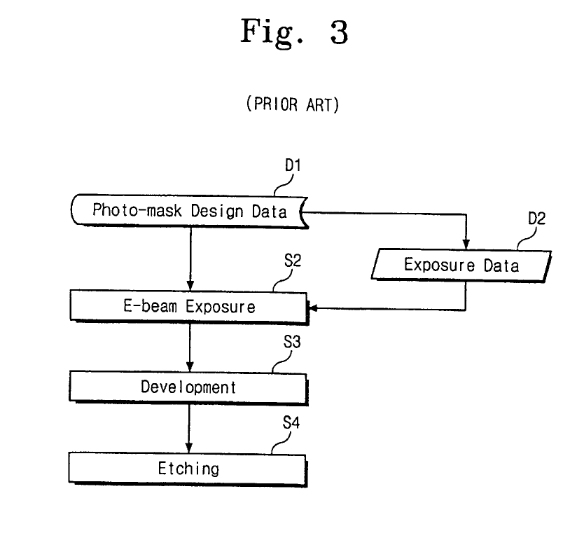

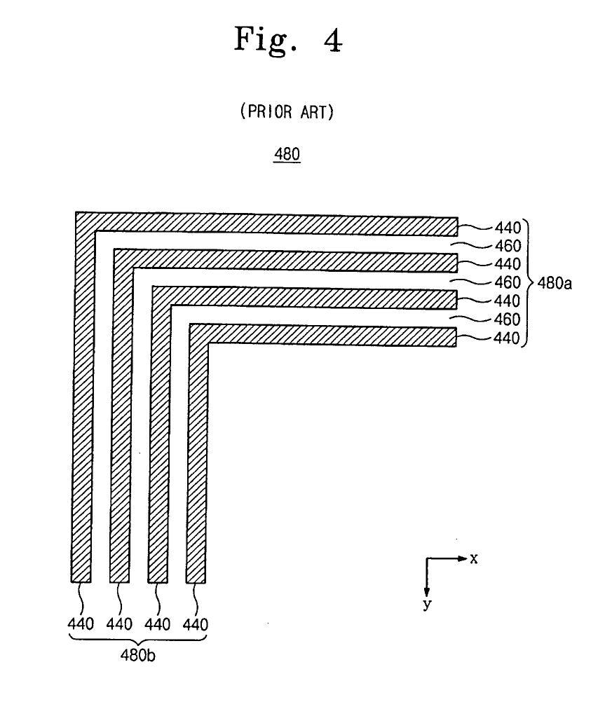

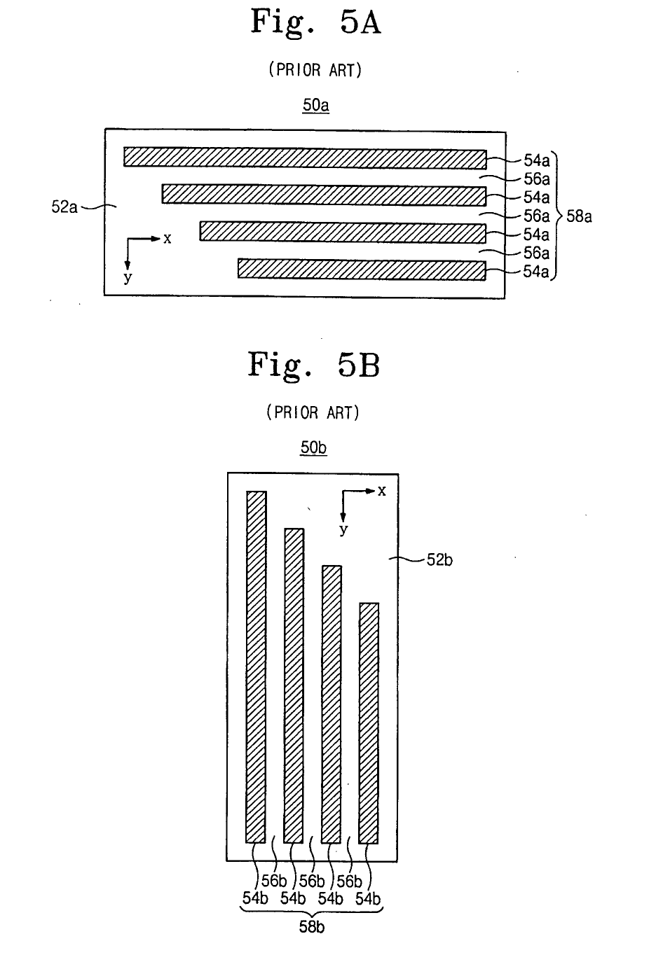

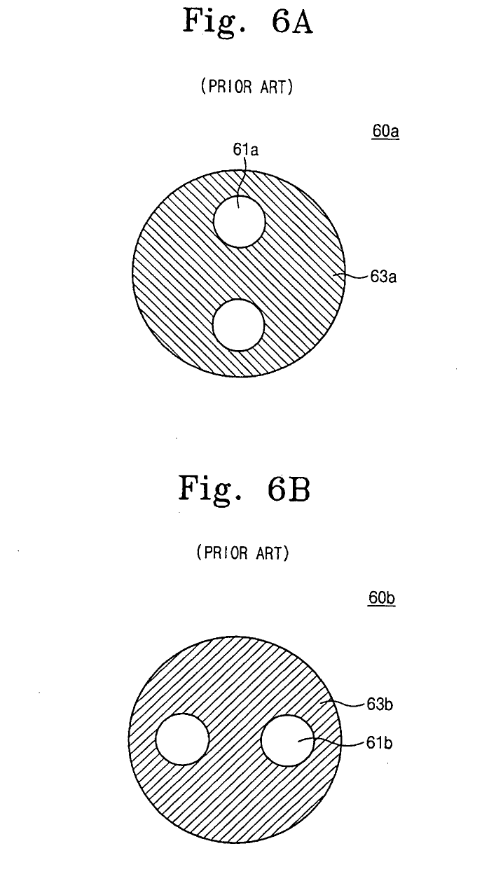

### DETAILED DESCRIPTION OF THE PREFERRED EMBODIMENTS

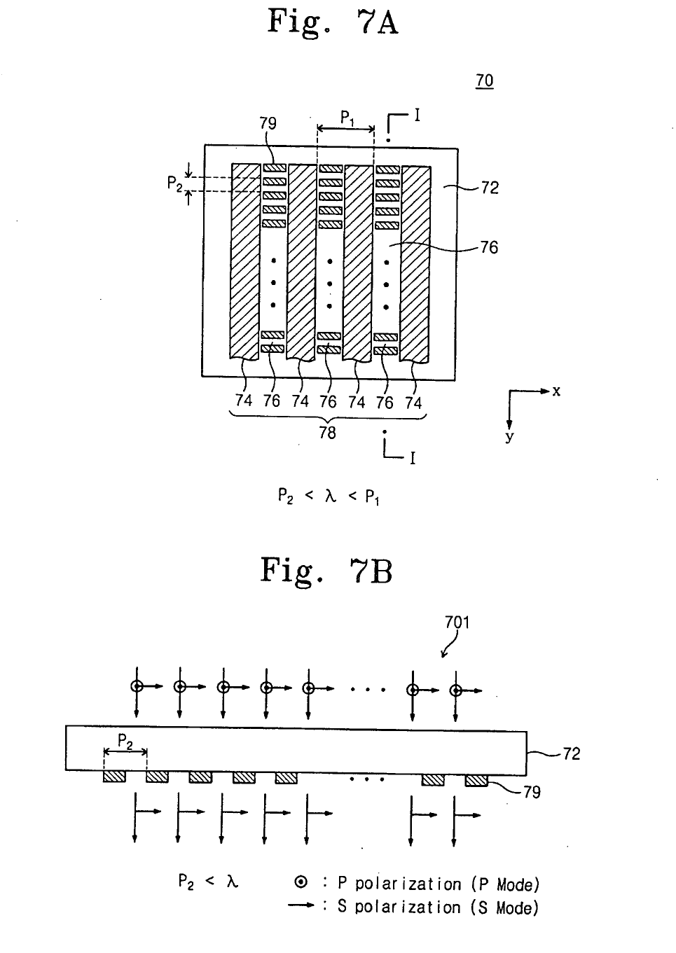

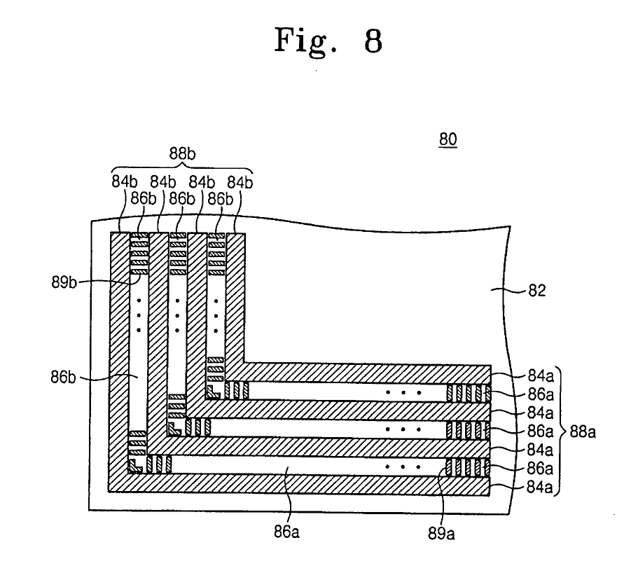

Referring to FIG. 7A, a photo-mask 70 according to the present invention includes a line/space pattern 78 oriented in a second direction (the direction of the Y axis) and a lattice pattern 79 oriented in a first direction (the direction of the X axis). The lines 74 of the line/space pattern 78 and the lattice pattern 79 are opaque and are formed on a transparent quartz substrate 72. The line/space pattern 78 consists of a series of parallel lines 74 extending in the second direction and spaces 76 defined between the lines 74. The lattice pattern 79 occupies the spaces 76 defined between the lines 74 of the line/space pattern 78 and consists of stripes extending perpendicular to the lines 74. The pitch P₁ of the line/space pattern 78 is larger than the wavelength λ of the light emitted by the light source of the exposure apparatus for which the photo-mask 70 is designed. The pitch P₂ of the lattice pattern 79 is smaller than the wavelength λ of the light source. Therefore, the lattice pattern 79 operates as a polarizer to transmit only those components of light oscillating in a direction perpendicular to the orientation of the gating pattern 79. In other words, the lattice pattern 79 transmits only those components of light oscillating parallel to the lines 74 of the line/space pattern 78, as will be described in more detail with reference to FIG. 7B.

Light can be represented by the sum of two components oscillating in planes perpendicular to each other. In the case of light incident on the photo-mask, the components considered will be a component oscillating in a plane parallel to the plane of incidence and a component oscillating in a plane perpendicular to the plane of incidence. The plane of incidence may be perpendicular to the line/space pattern. The component oscillating in a plane parallel to the plane of incidence will be referred to as P polarization (P mode) and the component oscillating in a plane perpendicular to the plane of incidence will be referred to as S polarization (S mode). S mode may be perpendicular to the direction of the grating pattern or may be parallel to the direction of the line/space pattern. On the other hand, P mode may be parallel to the direction of the grating pattern or ma be perpendicular to the direction of the line/space pattern.

Referring to FIG. 7B, the lattice pattern 79 transmits only the S polarization (the S mode) because the pitch P₂ of the lattice pattern 79 is smaller than the wavelength λ of the light 701. As a result, and according to the present invention, it is possible to pick up the image of the line/space pattern 78 with only the S mode of the light. Therefore, a precise image of the line/space pattern 78 can be transcribed onto a wafer.

FIG. 8 illustrates a photo-mask 80 including a perpendicular line/space pattern 88 according to the present invention. The perpendicular line/space pattern 88 includes line/space patterns 88a and 88b oriented in different directions. More specifically, the line/space pattern 88a is oriented in a first direction (the direction of the X axis) and the line/space pattern 88b is oriented in a second direction (the direction of the Y axis) perpendicular to the first direction. A first lattice pattern 89a consisting of stripes extending in the second direction (the direction of the Y axis) occupies spaces 86a between the lines 84a of the line/space pattern 88a. A second lattice pattern 89b consisting of stripes extending in the first direction (the direction of the X axis) occupies spaces 86b between the lines 84b of the line/space pattern 88b.

The first grating pattern 89a oriented in the second direction transmits only components of the light oscillating in the first direction (polarized in the direction of the X axis). The second lattice pattern 89b oriented in the first direction transmits only components of light oscillating in the second direction (polarized in the direction of the Y axis). Therefore, sharp images of both the line/space pattern 88a and the line/space pattern 88b are picked up by the S mode of the light. Accordingly, only one exposure process needs to be performed according to the present invention to produce the same effect as that which can only be produced by performing two exposure processes according to the prior art.

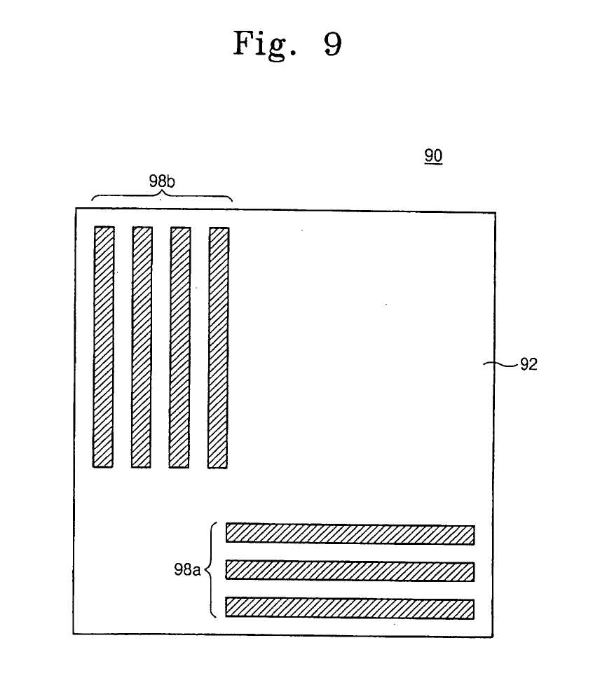

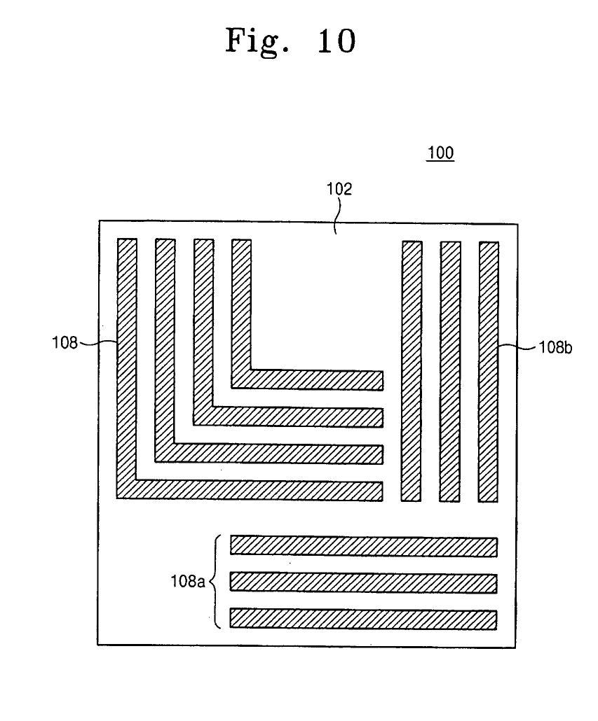

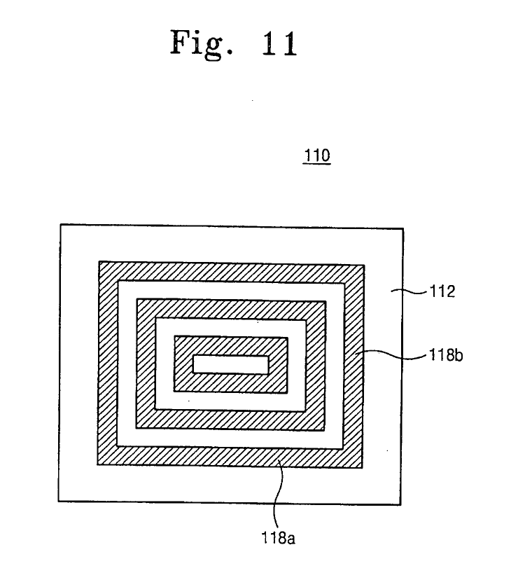

FIGS. 9 to 11 illustrate various photo-masks according to the present invention. Referring to FIG. 9, a photo-mask 90 includes line/space patterns 98a and 98b oriented in different directions (first and second directions perpendicular to each other); however, the line/space patterns 98a and 98b are separate from each other (discrete) unlike in the photo-mask of FIG. 8. Referring to FIG. 10, a photo-mask 100 includes a perpendicular line/space pattern 108 made up of line/space patterns oriented in first and second directions perpendicular to each other, a discrete line/space pattern 108a oriented in the first direction, and a discrete line/space pattern 108b oriented in the second direction. Referring to FIG. 11, a photo-mask 110 includes a rectangular line/space pattern 118.

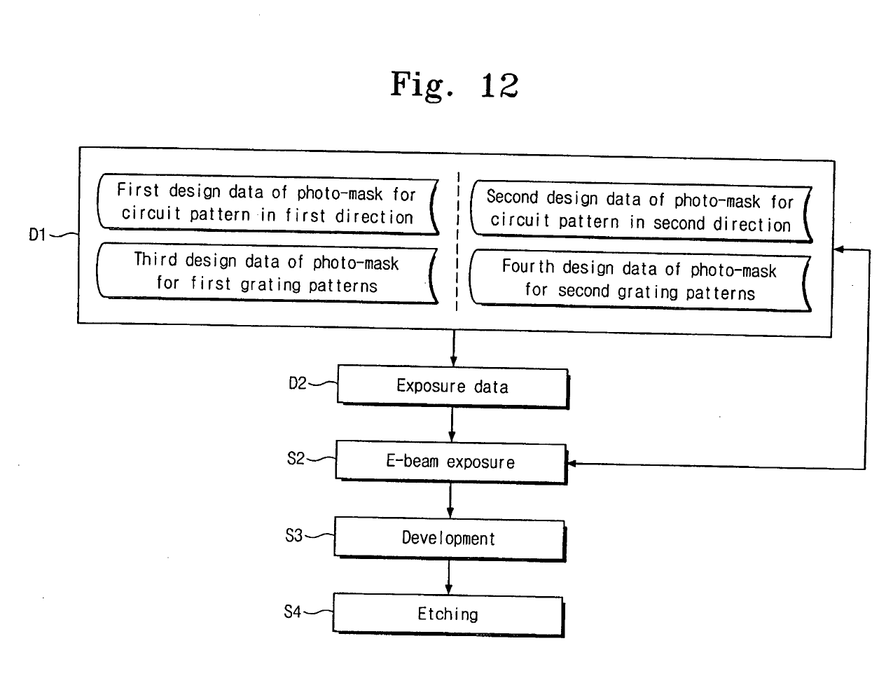

Methods of designing and fabricating the above-described photo-masks will now be described. As an example, a method of designing and fabricating a photo-mask having the perpendicular line/space pattern shown in FIG. 8 will be described with reference to FIGS. 8 and 12. The methods of designing and fabricating photo-masks having the other line/space patterns are similar to the method of FIG. 12. Therefore, detailed descriptions thereof will be omitted.

Referring to FIG. 12, a perpendicular line/space circuit pattern of a semiconductor device is designed using a computer program such as a CAD or OPUS program. The designed perpendicular line/space circuit pattern, as well as data of the exposure apparatus, e.g., the wavelength of the light emitted by the light source, is stored in a memory device as electronic data. According to the present invention, the electronic design data is processed to produce design data D1 of a photo-mask. The design data D1 includes first data representative of the line/space pattern 88a, second design data representative of the line/space pattern 88b, third design data representative of the first lattice pattern 89a occupying the spaces 86a defined between the lines 84a of the line/space pattern 88a, and fourth design data representative of the second lattice pattern 89b occupying the spaces 86b defined between the lines 84b of the line/space pattern 84b.

Then, an exposure process S2 is performed. In the exposure process S2, a predetermined region of a photoresist layer disposed on a quartz substrate is irradiated with an electron beam. The region irradiated in the exposure process S2 is determined by exposure data D2 extracted from the design data D1. The exposed photoresist layer then undergoes a development process S3 to form a photoresist pattern that exposes a chrome layer disposed under the photoresist layer. Then, the exposed chrome layer is plasma dry etched (S4) to form a chrome pattern that exposes the quartz substrate. The dry etching process S4 is performed using the photoresist pattern as an etching mask and the photoresist pattern is removed after the etching process. Thus, a perpendicular line/space pattern including diffraction patterns that function as a polarizer is formed.

Then, such a line/space pattern is illuminated using a modified illuminating system such that an image of the line/space pattern is transcribed to a photoresist layer on a wafer (WPR).

Hereinafter, such a modified illuminating system according to the present invention will be described. The modified illuminating system is optimized for the line/space pattern of the photo-mask. For example, when the photo-mask has a line/space circuit pattern oriented in a first direction (the direction of the X axis), a dipole modified illuminating system is used wherein two light transmission regions of the system are arrayed in the first direction (the direction of the X axis) and are implemented as polarizers that transmit light polarized in the first direction. Similarly, when the photo-mask has a line/space pattern oriented in a second direction (the direction of the Y axis), a dipole modified illuminating system is used wherein two light transmission regions of system are arrayed in the second direction (the direction of the Y axis) and are implemented as polarizers that transmit light polarized in the second direction.

On the other hand, when the photo-mask has line/space patterns that are oriented perpendicular to each other, an annular modified illuminating system and a dipole modified illuminating system may be used. In this case the annular light transmission region of the annular modified illuminating system is implemented as a polarizer that transmits light polarized in a first of the directions, and the two light transmission regions of the dipole modified illuminating system are arrayed in the first direction or second direction and are implemented as polarizers that transmit light polarized in the second direction. The regions where the light transmission regions of the annular and dipole modified illuminating systems overlap preferably transmit light that is not polarized. Alternatively, a quadrupole modified illuminating system may be used. In this case, two light transmission regions are arrayed in the first direction and are implemented as polarizers that transmit light polarized in the first direction, and two light transmission regions are arrayed in the second direction and are implemented as polarizers that transmit light polarized in the second direction. Theses illuminating systems may be realized in the form of composite polarization illuminating systems. Such composite polarization illuminating systems according to the present invention will now be described in more detail.

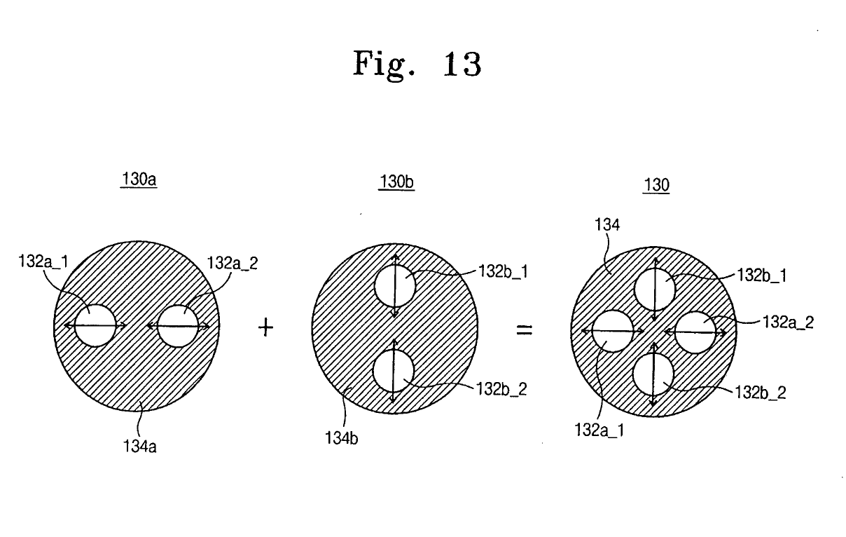

Referring to FIG. 13, a composite polarization illuminating system 130 consists of a first dipole modified illuminating system 130a having two light transmission regions 132a_1 and 132a_2 arrayed in the first direction (the direction of the X axis) in a shielding (opaque) region 134a, and a second dipole modified illuminating system 130b having two light transmission regions 130b_1 and 130b_2 arrayed in the second direction (the direction of the Y axis) in a shielding (opaque) region 134b. In FIG. 13, reference numeral 134 denotes the resultant shielding (opaque) region.

The light transmission regions 132a_1 and 132a_2 of the first dipole modified illuminating system 130a are implemented as polarizers that transmit light polarized in the first direction (the direction of the X axis). On the other hand, the light transmission regions 132b_1 and 132b_2 of the second dipole modified illuminating system 130b are implemented as polarizers that transmit light polarized in the second direction (the direction of the Y axis). Therefore, when the photo-mask of FIG. 8 is illuminated by light transmitted through the composite polarization illuminating system 130, light polarized in the first direction, i.e., the component of light passing through the light transmission regions 132a_1 and 132a_2, is blocked by the second lattice pattern 89b of the photo-mask 80. The component of the light polarized in the second direction, i.e., the component of the light that passes through the light transmission regions 132b_1 and 132b_2, is blocked by the first lattice pattern 89a of the photo-mask 80. Therefore, the image of the line/space pattern 88a is picked up by the light that passes through the light transmission regions 132a_1 and 132a_2 and the image of the line/space pattern 88b is picked up by light that passes through the light transmission regions 132b_1 and 132b_2 during an exposure process.

A quadrupole modified illuminating system may be used instead of two dipole modified illuminating systems. The quadrupole modified illuminating system has two light transmission regions arrayed in the first direction (the direction of the X axis) and two light transmission regions arrayed in the second direction (the direction of the Y axis). The light transmission regions in the first direction are implemented as polarizers that transmit light polarized in the first direction (the direction of the X axis). On the other hand, the light transmission regions in the second direction are implemented as polarizers that transmit light polarized in the second direction (the direction of the Y axis).

Such a composite polarization illuminating system 130 may be used for exposing a perpendicular line/space circuit pattern that does not have lattice patterns. In such a case, the light transmitted through the light transmission regions 132b_1 and 132b_2 arrayed in the second direction may influence the pick-up of the image of the line/space pattern oriented in the first direction.

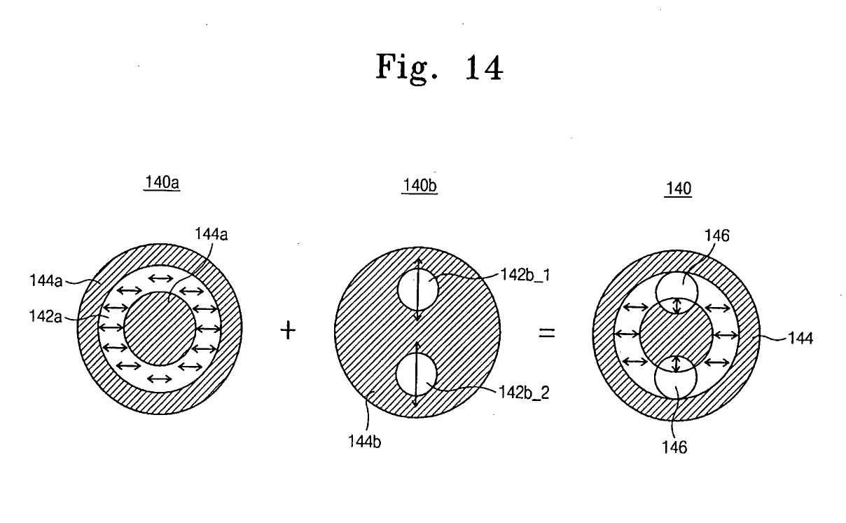

FIG. 14 illustrates another embodiment of a composite polarization modified illuminating system according to the present invention. The composite polarization modified illuminating system 140 according to this embodiment consists of two modified illuminating systems 140a and 140b implemented as polarizers that transmit light polarized in different directions. The first modified illuminating system 140a has an annular transmission region 142a within a shielding (opaque) region 144a. The annular transmission region is implemented as a polarizer that transmits light polarized in the first direction (the direction of the X axis). The second modified illuminating system 140b is a dipole modified illuminating system having two transmission regions 142b_1 and 142b_2 arrayed in the second direction (the direction of the Y axis) within a shielding (opaque) region 144b. The transmission regions 142b_1 and 142b_2 are implemented as polarizers that transmit light polarized in the second direction (the direction of the Y axis). Regions 146 in which the light transmission region 142a and the light transmission regions 142b_1 and 142b_2 overlap transmit light that is not polarized (or light from the original light source). The overlapping light transmission regions 146 transmit light of an intensity that is twice that of the light emitted by the original light source. Also, although the light transmission regions of the quadrupole illuminating system and the dipole illuminating system are shown as being circular in FIGs, the present invention is not so limited. Rather, the light transmission regions may have various shapes.

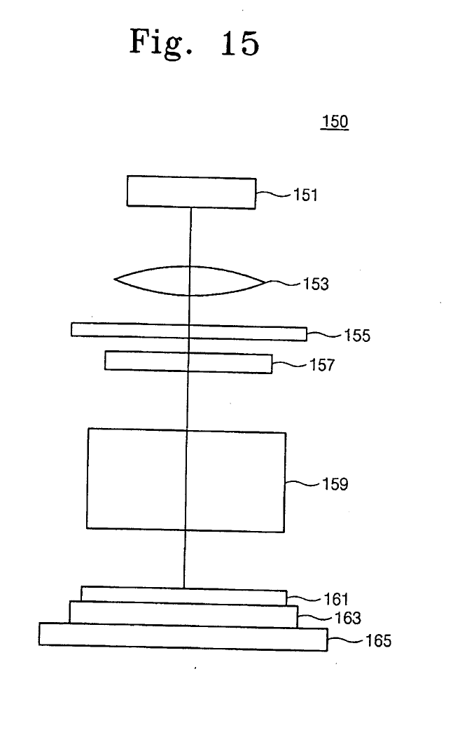

FIG. 15 illustrates an exposure apparatus 150 according to the present invention. The exposure apparatus 150 includes a light source 151 for generating a beam of light having a predetermined wavelength λ, a condensing lens 153 for condensing the beam of light emitted by the light source 151, a modified illuminating system 155, a photo-mask 157 bearing a pattern corresponding to a circuit pattern, a reduction projection lens 159 in front of the photo-mask 157, and a wafer stage 165 on which a wafer 163 coated with a layer of photoresist 161 is mounted.

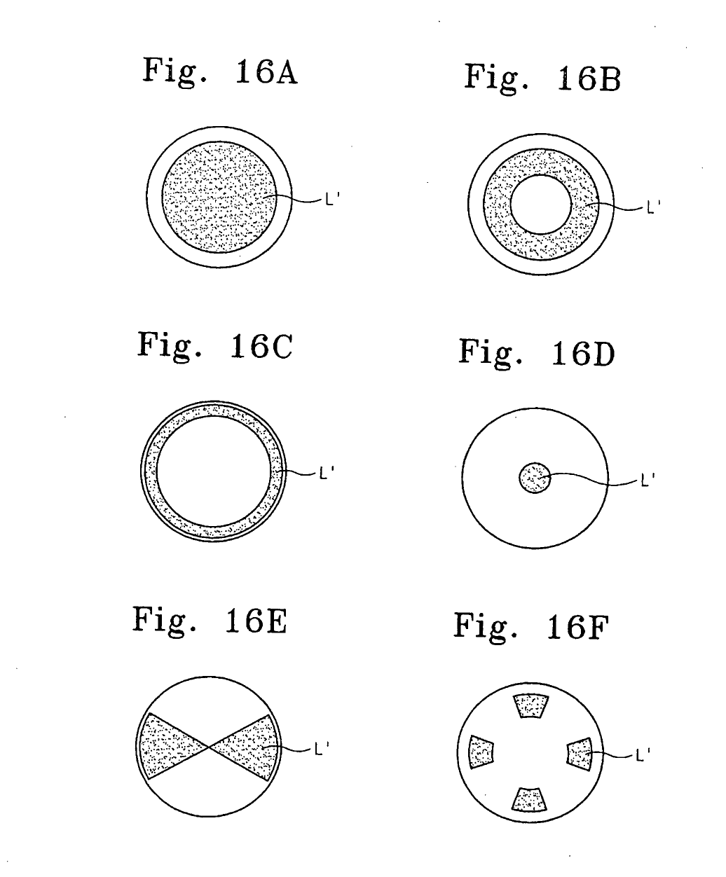

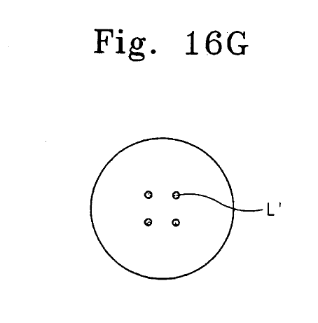

The illuminating system 155 is implemented as polarizers that polarize the light, emitted by the light source 151, in different directions. A method of spatially controlling the polarized state of the light and a system therefor will be described with respect to FIGS. 16A-16G.

The illuminating system 155 includes a beam shaper for converting a beam generated by the light source 151 into a partial beam L′ (corresponding to light transmission regions) having a spatial profile, such as that illustrated in any of FIGS. 16A to 16G. For example, the beam is converted into two sections in the above-described dipole illuminating system and is converted into four sections in the quadrupole illuminating system. Preferably, the beam shaper diffracts the beam of light to convert the beam into a partial beam. The beam shaper may thus comprise a diffraction optical element (DOE) or a hologram optical element (HOE).

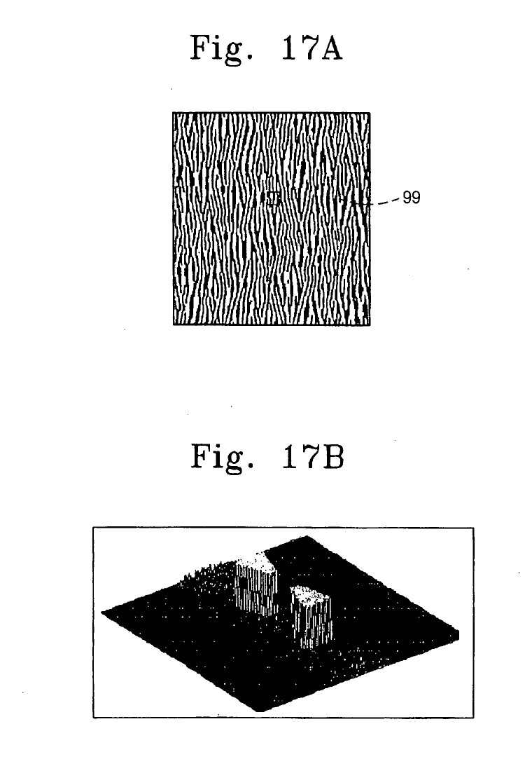

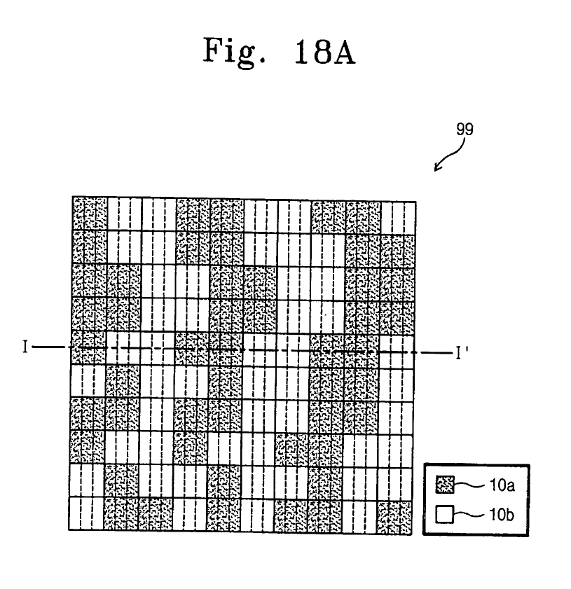

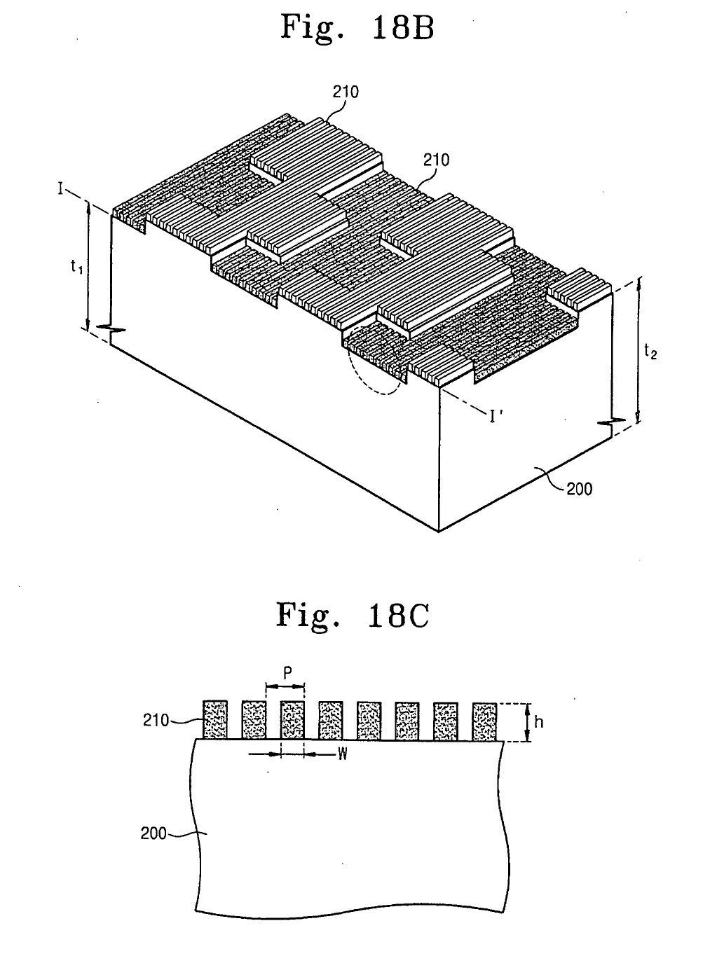

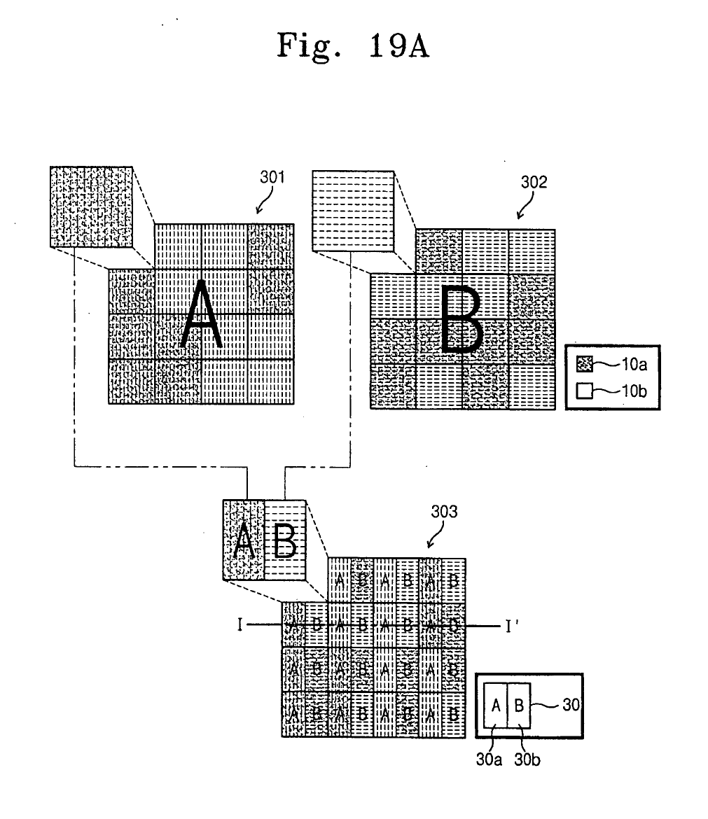

FIG. 17A is a plan view illustrating a hologram pattern employed by the beam shaper (for example, the HOE) according to the present invention. The hologram pattern is for forming the partial beam L′ having the shape illustrated in FIG. 16E or FIG. 17B. As illustrated in FIG. 18A (an enlargement of the region 99 of FIG. 17A), the hologram pattern comprises a spatial distribution of partial regions 10a, 10b having different physical characteristics. For example, the hologram pattern consists of first partial regions 10a and second partial regions 10b having different thicknesses as illustrated in FIGS. 18A and 18B.

The thicknesses of the partial regions 10a and 10b are determined by calculating the optical characteristics of those portions of the light that pass through the partial regions, respectively. Calculations of this type are typically performed by computer using Fourier transforms. The beam shaper is then fabricated by subjecting a substrate 200 to photolithography/etching processes after the thicknesses of the partial regions are so calculated. The calculated thicknesses are used for determining the depth to which each of regions of the substrate 200, corresponding to the partial regions, is etched.

Referring to FIG. 18B, the first partial regions 10a each have a first thickness t₁ and the second partial regions 10b each have a second thickness t₂ larger than the first thickness t₁. However, the partial regions 10a and 10b may have more than two different thicknesses.

The beam shaper constitutes a polarization controller for converting the incident beam of light into a polarized partial beam. To this end, the beam shaper comprises a polarization pattern 210 on a surface of the substrate 200. More specifically, the polarization pattern 210 is a unidirectional pattern formed on the partial regions 10a, 10b. As a result, the partial beam that is transmitted by the beam shaper is polarized.

The polarization pattern 210 may comprises a series of bars having a height h and a predetermined pitch P as illustrated in FIGS. 18B and 18C. The bars are preferably formed of a material having a refractive index of about 1.3 to 2.5 and an extinction index k of about 0 to 0.2. For example, the bars of the polarization pattern 210 may be of a material selected from the group consisting of ArF photoresist, SiN, and SiON.

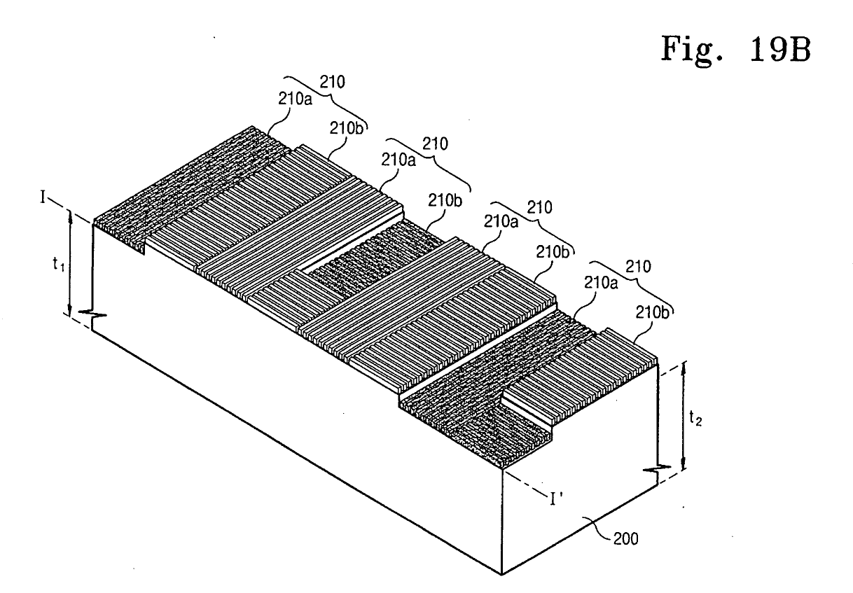

FIGS. 19A and 19B illustrate a polarization controller 303 according to the present invention for forming a partial beam having two sections polarized in directions perpendicular to each other. The polarization controller 303 may realized as a combination of a first virtual polarization controller 301 that can create a first section of a partial beam polarized in a first predetermined direction and a second virtual polarization controller 302 that can create a second section of a partial beam polarized in a second direction perpendicular to the first direction, as illustrated in FIG. 19A. Each of the first and second virtual polarization controllers 301 and 302 consist of first partial regions 10a, and second partial regions 10b that are thicker than the first partial regions 10a (as was illustrated in FIG. 18B). The first and second virtual polarization controllers 301 and 302 can thus be fabricated in the same way as the beam shaper of FIGS. 18A and 18B. However, the polarization controller 303 does not have to be fabricated from the virtual polarization controllers 301 and 302.

More specifically, the polarization controller 303 has a plurality of partial regions 30. Each of the respective partial regions 30 of the polarization controller 303 is a combination of the partial regions 10a and/or 10b located in the corresponding sections of the first and second virtual polarization controllers 301 and 302, as illustrated in FIG. 19A.

As with the beam shaper of FIGS. 18A and 18B, the distribution of the thicknesses of the first and second virtual polarization controllers 301 and 302 determines the profiles of the partial beams that pass through the first and second virtual polarization controllers 301 and 302, respectively. The direction of the polarization patterns on the first and second virtual polarization controllers 301 and 302 determines the polarization of the partial beams. Therefore, the sections of the beams that pass through the respective partial regions 30 of the polarization controller 303 exhibit physical characteristics (for example, profile and polarization) of the partial beams that can be separately created by the first and second virtual polarization controllers 301 and 302.

That is, according to the embodiment of the present invention illustrated in FIG. 19A, the partial regions 30 of the polarization controller 303 consist of first sub-regions 30a and second sub-regions 30b. The first sub-regions 30a have a thickness equal to the thickness of the partial regions located in the corresponding sections of the first virtual polarization controller 301 and the second sub-regions 30b have a thickness equal to the thickness of the partial regions located in the corresponding sections of the second virtual polarization controller 302. As a result, the profile of the partial beam that passes through the polarization controller 303 is the same as the profile that would be obtained by combining the partial beams that pass through the first and second virtual polarization controllers 301 and 302, respectively.

Also, the first sub-regions 30a and the second sub-regions 30b include first polarization patterns 210a and second polarization patterns 210b oriented in the same directions as the polarization patterns of the partial regions 10a and/or 10b located at the corresponding sections of the first and second virtual polarization controllers 301 and 302. Therefore, the sections of the beam that pass through the first sub-regions 30a have the same states of polarization as the beam that passes through the first virtual polarization controller 301, and the sections of the beam that pass through the second sub-regions 30b have the same states of polarization as the beam that passes through the second virtual polarization controller 302.

The polarization controller according to the present invention can be generalized as follows so that a polarization controller that can be used for a more complicated case can be fabricated. More specifically, the polarization controller according to the present invention can be conceived as including n (n≧1) partial regions 30. Each of the partial regions 30 consists of m (m≧1) sub-regions. Thus, the polarization controller consists of n×m sub-regions.

In this case, the number of sub-regions 30 is that required for forming a partial beam having a desired profile. The sub-regions will thus have various thicknesses in order to create beam sections having different profiles. According to the present invention, the thickness of the kth (1≦k≦m) lower region is a parameter that establishes the profile of the section of the partial beam passing through the kth sub-region. Also, according to the present invention, polarization patterns providing the same direction of polarization are provided at the jth sub-region (1≦j≦m) of the ith (1≦i≦n) partial region and the jth sub-region of the kth (k≠i and 1≦k≦n) partial region. Thus, a similar bar pattern 210 is provided in each partial region.

As described above, according to the present invention, it is possible to execute only one exposure process to obtain the same effect that can only be obtained by performing two exposure processes according to the prior art. Therefore, the yield of the photolithographic process is dramatically improved by practicing the present invention.

Finally, although the present invention has been particularly shown and described with reference to the preferred embodiments thereof, it will be understood by those skilled in the art that various changes in form and details may be made thereto without departing from the true spirit and scope of the invention as defined by the appended claims.

What is claimed is:

1. A photo-mask for use in transmitting an image corresponding to that of a circuit pattern when illuminated with light of a given wavelength, the photo-mask comprising:
a substrate that is transparent with respect to the light of the given wavelength;
at least one line/space pattern disposed on a surface of the substrate, the line/space pattern including series of lines that extend in a direction parallel to one another so as to define spaces therebetween, said lines being substantially opaque with respect to the light; and
a respective lattice pattern occupying the spaces defined between the lines of each said line/space pattern, the lattice pattern constituted by a series of stripes that are substantially opaque with respect to the light and extend perpendicular to the direction in which the lines of the line/space pattern extend, the stripes of the lattice pattern having a pitch that is smaller than the wavelength of the light.

2. The photo-mask as set forth in claim 1, wherein the at least one line/space pattern comprises a first line/space pattern including a first series of lines that extend in a first direction parallel to one another, and a second line/space pattern including a second series of lines that extend parallel to one another in a second direction perpendicular to the first direction.

3. The photo-mask as set forth in claim 2, wherein the first and second series of lines are contiguous.

4. A composite polarization modified illuminating system for illuminating a photo-mask using light from a light source, wherein the illuminating system comprises: a shielding region that is substantially opaque with respect to the light, and a plurality of light transmission regions defined within the field of the shielding region, said light transmission regions being substantially transparent with respect to the light and comprising polarizers that polarize the light incident thereon in different directions, respectively.

5. The composite polarization modified illuminating system as set forth in claim 4, wherein the light transmission regions overlap, and the area of overlap of the light transmission regions transmits incident light that is not polarized.

6. The composite polarization modified illuminating system as set forth in claim 5, wherein the polarizers polarize the light incident on the transmission regions in directions that are perpendicular to each other.

7. The composite polarization modified illuminating system as set forth in claim 6, wherein the light transmission regions overlap each other, and the area of overlap of the light transmission regions transmits incident light that is not polarized.

8. The composite polarization modified illuminating system as set forth in claim 4, wherein the light transmission regions include a first pair of openings in the field of the shielding region spaced apart from one another in a first direction, and a second pair of openings in the field of the shielding region spaced apart from one another in a second direction, the polarizers occupying the pairs of openings, respectively.

9. The composite polarization modified illuminating system as set forth in claim 8, wherein the first and second directions are perpendicular to each other, and the polarizer that occupies the first pair of openings polarizes the light incident thereon in said first direction, and the polarizer that occupies the second pair of openings polarizes the light incident thereon in said second direction.

10. The composite polarization modified illuminating system as set forth in claim 4, wherein the light transmission regions include a first annular opening in the field of the shielding region, and a pair of openings in the field of the shielding region spaced apart from one another in a first direction, the polarizers occupying the annular opening and the pair of openings, respectively.

11. The composite polarization modified illuminating system as set forth in claim 10, wherein the first and second directions are perpendicular to each other, and the polarizer that occupies the pair of openings polarizes the light incident thereon in said first direction, and the polarizer that occupies the annular opening polarizes the light incident thereon in a second direction perpendicular to the first direction.

12. The composite polarization modified illuminating system as set forth in claim 11, wherein each of the openings of the first pair overlaps the annular opening in the field of the shielding region, and the area of overlap transmits incident light that is not polarized.

13. An exposure apparatus comprising:
a light source that emits light of a given wavelength;
a photo-mask positioned in the exposure apparatus such that light emitted by the light source is incident thereon, the photo-mask comprising a substrate that is transparent with respect to the light emitted by the light source, a first line/space pattern including a first series of lines that extend in a first direction parallel to one another so as to define spaces therebetween, a second line/space pattern including a second series of lines that extend parallel to one another in a second direction so as to define spaces therebetween, the lines of the first and second line/space pattern being substantially opaque with respect to the light emitted by the light source; and
a modified illuminating system interposed in the exposure apparatus between the light source and the photo-mask to illuminate a region of the photo-mask with the light emitted by the light source, the modified illuminating system comprising first and second polarizers that polarize the light incident thereon in said first and second directions, respectively.

14. The exposure apparatus as set forth in claim 13, wherein the modified illuminating system comprises a composite polarization modified illuminating system having a shielding region that is substantially opaque with respect to the light, and a plurality of light transmission regions defined within the field of the shielding region, said light transmission regions being substantially transparent with respect to the light and comprising first and second polarizers that polarize the light incident thereon in said first and second directions, respectively.

15. The exposure apparatus as set forth in claim 14, wherein the light transmission regions overlap, and the area of overlap of the light transmission regions transmits incident light that is not polarized.

16. The exposure apparatus as set forth in claim 14, wherein each of the light transmission regions has a dipole shape.

17. The exposure apparatus as set forth in claim 14, wherein one of the light transmission regions has a dipole shape, and the other of the light transmission regions has an annular shape.

18. The exposure apparatus as set forth in claim 14, wherein the photo-mask also comprises a first lattice pattern occupying the spaces defined between the lines of the first line/space pattern, and a second lattice pattern occupying the spaces defined between the lines of the second line/space pattern, the first lattice pattern constituted by a series of first stripes that are substantially opaque with respect to the light and extend perpendicular to the direction in which the lines of the first line/space pattern extend, the first stripes having a pitch that is smaller than the wavelength of the light, and the second lattice pattern constituted by a series of second stripes that are substantially opaque with respect to the light and extend perpendicular to the direction in which the lines of the second line/space pattern extend, the second stripes having a pitch that is smaller than the wavelength of the light.

19. The exposure apparatus as set forth in claim 18, wherein the light transmission regions overlap, and the area of overlap of the light transmission regions transmits incident light that is not polarized.

20. The exposure apparatus as set forth in claim 18, wherein each of the light transmission regions has a dipole shape.

21. The exposure apparatus as set forth in claim 18, wherein one of the light transmission regions has a dipole shape, and the other of the light transmission regions has an annular shape.

22. The exposure apparatus as set forth in claim 13, wherein the first and second directions are perpendicular to each other.

23. A method of forming a line/space circuit pattern, said method comprising:
providing a substrate having a layer of photoresist thereon;
producing light having a given wavelength;
directing the light onto the layer of photoresist through a photo-mask comprising a substrate that is transparent with respect to the light, a first line/space pattern including a first series of lines that extend in a first direction parallel to one another so as to define spaces therebetween, and a second line/space pattern including a second series of lines that extend parallel to one another in a second direction so as to define spaces therebetween, the first and second directions being non-parallel and the lines of the first and second line/space pattern being substantially opaque with respect to the light emitted by the light source, whereby the image of the line/space patterns of the photo-mask is picked up by the light and transcribed onto the layer of photoresist;
polarizing the light in the first and second directions before the light is transmitted from the photo-mask;
developing the exposed layer of photoresist to thereby form a photoresist pattern; and
etching the substrate using the photoresist pattern as a mask.
